(19) United States
(12) Patent Application Publication
(10) Pub. No.: US 2024/0097645 A1
(43) Pub. Date: Mar. 21, 2024

(54) ACOUSTIC WAVE DEVICE

(71) Applicant: Murata Manufacturing Co., Ltd., Nagaokakyo-shi (JP)

(72) Inventor: Sho NAGATOMO, Nagaokakyo-shi (JP)

(21) Appl. No.: 18/525,943

(22) Filed: Dec. 1, 2023

Related U.S. Application Data
(63) Continuation of application No. PCT/JP2022/028144, filed on Jul. 20, 2022.

(30) Foreign Application Priority Data
Jul. 21, 2021 (JP) 2021-120520

(51) Int. Cl. H03H 9/02; C22C 27/02; H03H 9/145; H03H 9/25

(52) U.S. Cl. CPC H03H 9/02834; C22C 27/02; H03H 9/02559; H03H 9/02866; H03H 9/145; H03H 9/25

(57) ABSTRACT

An acoustic wave device includes a piezoelectric substrate including an acoustic reflection layer and a piezoelectric layer on the acoustic reflection layer, and an IDT electrode on the piezoelectric substrate and including electrode fingers. When a wavelength defined by an electrode finger pitch of the IDT electrode is λ, a thickness of the piezoelectric layer is about 3λ or smaller. The electrode fingers include at least one electrode layer. A sum total of a thickness of the at least one electrode layer converted based on a density ratio of the at least one electrode layer and Al assuming that the at least one electrode layer includes Al is a same or larger than the thickness of the piezoelectric layer.

### CROSS REFERENCE TO RELATED APPLICATIONS

This application claims the benefit of priority to Japanese Patent Application No. 2021-120520 filed on Jul. 21, 2021 and is a Continuation application of PCT Application No. PCT/JP2022/028144 filed on Jul. 20, 2022. The entire contents of each application are hereby incorporated herein by reference.

### BACKGROUND OF THE INVENTION

### 1. Field of the Invention

The present invention relates to acoustic wave devices.

### 2. Description of the Related Art

Conventionally, acoustic wave filter devices are widely used for, for example, filters of cellular phones. Japanese Patent No. 5835480 discloses one example of an acoustic wave device. In this acoustic wave device, a support substrate, a high acoustic velocity film, a low acoustic velocity film, and a piezoelectric film are laminated. An interdigital transducer electrode (IDT) is provided on the piezoelectric film. By making a film thickness of the high acoustic velocity film within a given range, both of suppressing leakage of acoustic wave energy and leaking a wave which becomes spurious are achieved.

In the acoustic wave device in Japanese Patent No. 5835480, the piezoelectric film is joined to the support substrate with the high acoustic velocity film and the low acoustic velocity film interposed therebetween. In such an acoustic wave device, an electromechanical coupling coefficient is likely to be larger when compared to an acoustic wave device including a piezoelectric substrate but not including a high acoustic velocity film. As a result, an absolute value of a difference ΔTCV between temperature coefficients of acoustic velocity at a resonant point and an anti-resonant point tends to be large. In this case, since widths of change at the resonant point and at the anti-resonant point due to change in temperature are different, stability in electrical characteristics of the acoustic wave device may be damaged.

### SUMMARY OF THE INVENTION

Preferred embodiments of the present invention provide acoustic wave devices in each of which an absolute value of a difference ΔTCV between temperature coefficients of acoustic velocity at a resonant point and an anti-resonant point is reduced.

An acoustic wave device according to a preferred embodiment of the present invention includes a piezoelectric substrate including an acoustic reflection layer and a piezoelectric layer on the acoustic reflection layer, and an IDT electrode on the piezoelectric substrate and including a plurality of electrode fingers. When a wavelength defined by an electrode finger pitch of the IDT electrode is λ, a thickness of the piezoelectric layer is about 3λ or smaller. Each of the plurality of electrode fingers includes at least one electrode layer. A sum total of a thickness of the at least one electrode layers converted based on a density ratio of the at least one electrode layer and Al assuming that the at least one electrode layer includes Al is a same or larger than the thickness of the piezoelectric layer.

An acoustic wave device according to a preferred embodiment of the present invention includes a piezoelectric substrate including a high-acoustic-velocity material layer and a piezoelectric layer on the high-acoustic-velocity material layer, and an IDT electrode on the piezoelectric substrate and including a plurality of electrode fingers. An acoustic velocity of a bulk wave which propagates in the high-acoustic-velocity material layer is higher than an acoustic velocity of an acoustic wave which propagates in the piezoelectric layer. When a wavelength defined by an electrode finger pitch of the IDT electrode is λ, a thickness of the piezoelectric layer is about 3λ or smaller. The plurality of electrode fingers include at least one electrode layer. A sum total of a thickness of the at least one electrode layer converted based on a density ratio of the at least one electrode layer and Al assuming that the at least one electrode layer includes Al is a same or larger than the thickness of the piezoelectric layer.

With acoustic wave devices according to preferred embodiments of the present invention, an absolute value of a difference ΔTCV between temperature coefficients of acoustic velocity at a resonant point and an anti-resonant point is reduced.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a plan view of an acoustic wave device according to a first preferred embodiment of the present invention.

FIG. 2 is a sectional view taken along a line I-I in FIG. 1.

FIG. 3 is a diagram illustrating a relationship between a temperature coefficient of elasticity TCm of an electrode finger, a wavelength-based normalized thickness t of the electrode finger, and a difference ΔTCV in a temperature coefficient of acoustic velocity.

FIG. 4 is a diagram illustrating a relationship between the temperature coefficient of elasticity TCm of the electrode finger, a normalized thickness of the electrode finger, and the difference ΔTCV in the temperature coefficient of acoustic velocity.

FIG. 5 is a diagram illustrating a relationship between the temperature coefficient of elasticity TCm of the electrode finger, the normalized thickness of the electrode finger, and a temperature coefficient of acoustic velocity TCVr at a resonant point.

FIG. 6 is a diagram illustrating a relationship between a percentage of Mo content and dc44/dT in NbMo.

FIG. 7 is an elevational cross-sectional view of an acoustic wave device according to a modification of the first preferred embodiment of the present invention.

FIG. 8 is an elevational cross-sectional view of an acoustic wave device according to a second preferred embodiment of the present invention.

FIG. 9 is an elevational cross-sectional view of an acoustic wave device according to a third preferred embodiment of the present invention.

### DETAILED DESCRIPTION OF THE PREFERRED EMBODIMENTS

Hereinafter, the present invention is clarified by preferred embodiments of the present invention described below with reference to the drawings.

Each preferred embodiment described herein is merely an example, and partial replacement or combination of configurations between different preferred embodiments is possible.

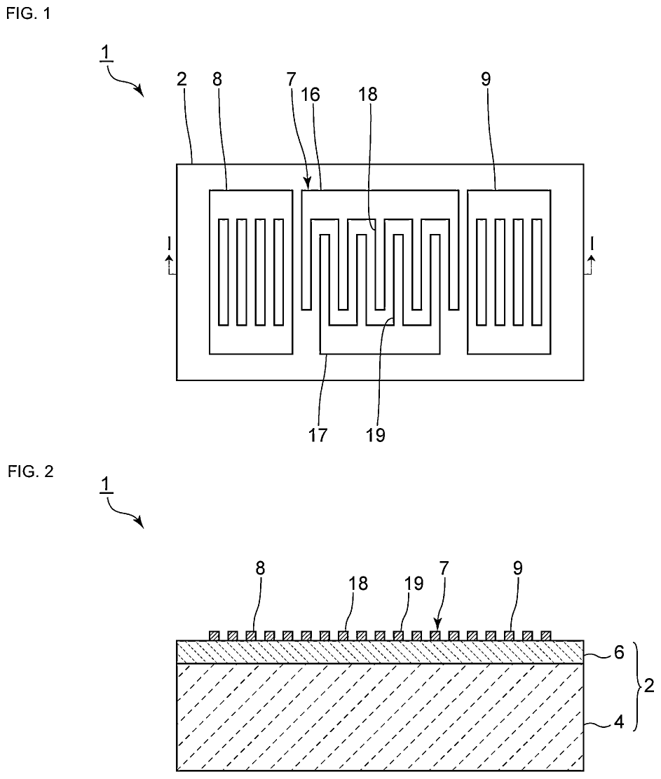

FIG. 1 is a plan view of an acoustic wave device according to a first preferred embodiment of the present invention. FIG. 2 is a sectional view taken along a line I-I in FIG. 1.

As illustrated in FIG. 1, an acoustic wave device 1 includes a piezoelectric substrate 2. As illustrated in FIG. 2, the piezoelectric substrate 2 includes a high-acoustic-velocity support substrate 4 as a high-acoustic-velocity material layer, and a piezoelectric layer 6. The piezoelectric layer 6 is provided on the high-acoustic-velocity support substrate 4.

An IDT electrode 7 is provided on the piezoelectric layer 6. By alternating-current voltage being applied to the IDT electrode 7, an acoustic wave is excited. In the present preferred embodiment, an SH mode is excited as a main mode. On both sides of the IDT electrode 7 in a propagation direction of an acoustic wave on the piezoelectric layer 6, corresponding reflectors 8 and 9 as one pair are provided. The acoustic wave device 1 of the present preferred embodiment is, for example, a surface acoustic wave resonator. However, the acoustic wave device may be, for example, a filter device or a multiplexer including a plurality of acoustic wave resonators.

Lithium tantalate, for example, is used for the piezoelectric layer 6. More specifically, for example, 42YX-LiTaO₃ is used for the piezoelectric layer 6. However, cut-angles of the piezoelectric layer 6 are not limited to those described above.

The high-acoustic-velocity material layer is a layer where an acoustic velocity is relatively high. In the present preferred embodiment, the high-acoustic-velocity material layer is the high-acoustic-velocity support substrate 4. An acoustic velocity of a bulk wave which propagates in the high-acoustic-velocity material layer is higher than an acoustic velocity of an acoustic wave which propagates in the piezoelectric layer 6. In the acoustic wave device 1, for example, silicon is used for the high-acoustic-velocity support substrate 4. However, a material of the high-acoustic-velocity material layer is not limited to that described above. For example, the following materials may be used: a piezoelectric material (for example, aluminum nitride, lithium tantalate, lithium niobate, and a crystal), ceramics (for example, alumina, sapphire, magnesia, silicon nitride, silicon carbide, zirconia, cordierite, mullite, steatite, forsterite, spinel, and sialon), a dielectric (for example, aluminum oxide, silicon oxynitride, diamond-like carbon (DLC), and diamond), a semiconductor (for example, silicon), or a material whose main component is the material described above. The spinel includes an aluminum compound containing one or more element(s) selected from Mg, Fe, Zn, Mn, and the like, and oxygen, for example. The spinel is, for example, MgAl₂O₄, FeAl₂O₄, ZnAl₂O₄, and MnAl₂O₄.

In the piezoelectric substrate 2, the high-acoustic-velocity support substrate 4 as the high-acoustic-velocity material layer and the piezoelectric layer 6 are laminated. Therefore, an acoustic wave can effectively be confined at the piezoelectric layer 6 side. In preferred embodiments of the present invention, the piezoelectric substrate is not limited to include the high-acoustic-velocity material layer, and may include an acoustic reflection layer which will be described later.

The IDT electrode 7 includes a first busbar 16, a second busbar 17, a plurality of first electrode fingers 18, and a plurality of second electrode fingers 19. The first busbar 16 and the second busbar 17 are opposed to each other. One ends of the plurality of first electrode fingers 18 are connected to the first busbar 16. One ends of the plurality of second electrode fingers 19 are connected to the second busbar 17. The plurality of first electrode fingers 18 and the plurality of second electrode fingers 19 are interdigitated with each other. The first electrode finger 18 and the second electrode finger 19 may simply be referred to below as an electrode finger.

The IDT electrode 7 includes one electrode layer. The IDT electrode 7 may include at least one electrode layer. Therefore, the IDT electrode 7 may include a plurality of electrode layers.

The electrode layer of the IDT electrode 7 includes, for example, NbMo. NbMo is an alloy of Nb and Mo. However, a material of the electrode layer is not limited to that described above. As the material of the electrode layer, for example, NiTi, CoPd, NiFe, or the like may be used. At least one electrode layer preferably includes an alloy including at least one of Nb and Pd. For the pair of reflectors 8 and 9, a material the same as or similar to the material for the IDT electrode 7 is used.

Herein, an Al conversion thickness is used as a thickness of the electrode layer. The Al conversion thickness of the electrode layer is a thickness of the electrode layer converted based on a density ratio of the electrode layer and Al included in the electrode layer. Assuming that a density of the electrode layer is ρe, a density of Al is ρAl, and a density ratio is r=ρe/ρAl, and that the thickness of the electrode layer is te, and the Al conversion thickness of the electrode layer is tn, tn=r×te is satisfied. When the electrode finger includes a plurality of electrode layers, the Al conversion thickness of the electrode finger is the sum total of the Al conversion thicknesses of the plurality of electrode layers. For example, when the electrode finger is a multilayer body including m electrode layers, and assuming that an Al conversion thickness of a kth electrode layer is tnk, the Al conversion thickness of the electrode finger is Σtnk (1≤k≤m). When the electrode finger includes only one electrode layer, the sum total of the Al conversion thickness of the electrode layer is the Al conversion thickness of the one electrode layer.

Assume that a wavelength defined by an electrode finger pitch of the IDT electrode is λ. The electrode finger pitch is a distance between centers of the first electrode finger 18 and the second electrode finger 19 adjacent to each other. Assuming that the electrode finger pitch is p, a period of the plurality of electrode fingers is about 2p, and λ=2p is also satisfied.

Features of the present preferred embodiment are that the piezoelectric substrate 2 includes the high-acoustic-velocity support substrate 4 as the high-acoustic-velocity material layer, a thickness of the piezoelectric layer 6 is about 3λ or smaller, and the sum total of the Al conversion thickness of the electrode layer of the electrode finger is at or larger than the thickness of the piezoelectric layer 6. The thickness of the piezoelectric layer 6 is about 3λ or smaller, which is thin. Therefore, contribution of the layer in the piezoelectric substrate 2, other than the piezoelectric layer 6, to electrical characteristics of the acoustic wave device 1 can be increased. Moreover, since the piezoelectric substrate 2 includes the high-acoustic-velocity material layer, insertion loss can be reduced when the acoustic wave device 1 is used for a filter device. In addition to this, since the sum total of the Al conversion thickness of the electrode layer is at or larger than the thickness of the piezoelectric layer 6, temperature characteristics can be improved. More specifically, an absolute value of a difference ΔTCV [ppm/K] between temperature coefficients of acoustic velocity at a resonant point and an anti-resonant point can be reduced. Advantageous effects to reduce the difference ΔTCV in the temperature coefficient of acoustic velocity is described below in detail.

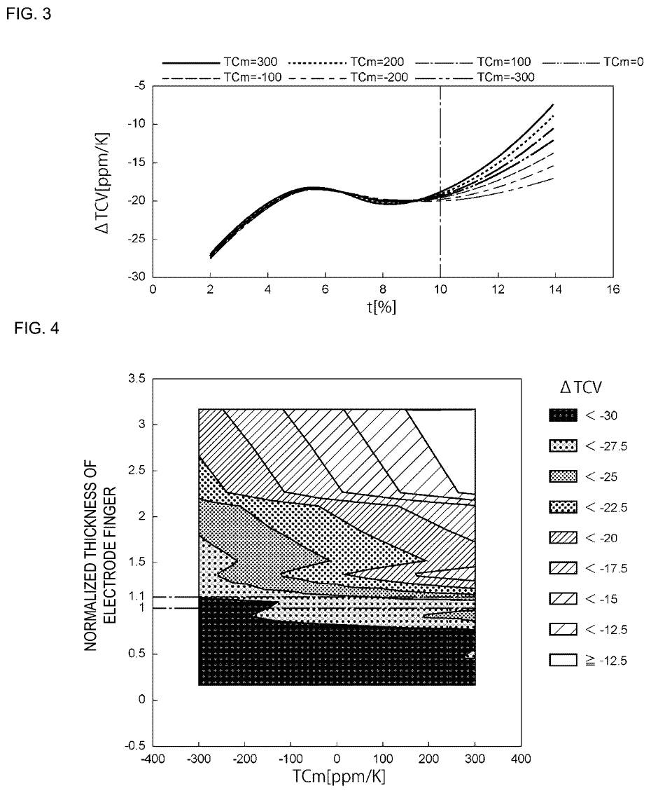

When an acoustic wave is in a leaking state, the piezoelectric layer has predominant influence on each characteristic of the acoustic wave. On the other hand, when an acoustic wave is in an non-leaking state, a displacement distribution of the acoustic wave concentrates at a surface of the piezoelectric layer and the electrode finger. Therefore, contribution of the electrode finger to each characteristic of the acoustic wave increases. With reference to FIG. 3 below, an example of cases in which the acoustic wave is in the leaking state and in which the acoustic wave is in the non-leaking state is described. Then, an advantageous improvement effect of the temperature characteristics will be described.

Through simulation, in each of cases in which a temperature coefficient of elasticity TCm [ppm/K] of the electrode finger was varied, a relationship between a wavelength-based normalized thickness t [%] of the electrode finger and the difference ΔTCV in the temperature coefficient of acoustic velocity was derived. The wavelength-based normalized thickness t of the electrode finger is a thickness of the electrode finger normalized by the wavelength λ. Assuming that the thickness of the electrode finger is about 1λ, t=100% is satisfied. In this simulation, the IDT electrode includes Mo, for example.

FIG. 3 is a diagram illustrating the relationship between the temperature coefficient of elasticity TCm of the electrode finger, the wavelength-based normalized thickness t of the electrode finger, and the difference ΔTCV in the temperature coefficient of acoustic velocity.

As illustrated in FIG. 3, when the wavelength-based normalized thickness t of the electrode finger is smaller than about 10%, at any value of the temperature coefficient of elasticity TCm of the electrode finger, the difference ΔTCV between the temperature coefficients of acoustic velocity at the resonant point and the anti-resonant point tends to approach zero as the value of the wavelength-based normalized thickness t increases. When the wavelength-based normalized thickness t is smaller than about 10%, regardless of the temperature coefficient of elasticity TCm, the difference ΔTCV in the temperature coefficient of acoustic velocity is the same or substantially the same. On the other hand, when the wavelength-based normalized thickness t is about 10% or larger, it can be seen that the difference ΔTCV in the temperature coefficient of acoustic velocity largely depends on the temperature coefficient of elasticity TCm.

This is because, when the wavelength-based normalized thickness t of the electrode finger is smaller than about 10%, the SH mode which is the main mode is in the leaking state, and when the wavelength-based normalized thickness t is about 10% or larger, the SH mode is in the non-leaking state. More specifically, when the wavelength-based normalized thickness t is approximately 10%, an acoustic velocity of the SH mode is the same or substantially the same as an acoustic velocity of a slow transversal wave which propagates in the piezoelectric layer. When the wavelength-based normalized thickness t is smaller than about 10% and the acoustic velocity of the SH mode is higher than the acoustic velocity of the slow transversal wave, the SH mode is in the leaking state. On the other hand, when the wavelength-based normalized thickness t is about 10% or larger and the acoustic velocity of the SH mode is lower than the acoustic velocity of the slow transversal wave, the SH mode is in the non-leaking state. In the non-leaking state, the SH mode is in a Love wave state.

When the SH mode is in the leaking state, the piezoelectric layer is predominant to the electrical characteristics of the acoustic wave device. On the other hand, when the SH mode is in the non-leaking state, the difference ΔTCV between the temperature coefficients of acoustic velocity at the resonant point and the anti-resonant point depends on not only the piezoelectric layer, but also the temperature coefficient of elasticity TCm of the electrode finger. As illustrated in FIG. 3, it can be seen that, as the temperature coefficient of elasticity TCm increases in a positive direction, the difference ΔTCV in the temperature coefficient of acoustic velocity approaches zero.

Next, it is described that the configuration of the present preferred embodiment, in which the sum total of the Al conversion thickness of the electrode layer of the electrode finger is at or larger than the thickness of the piezoelectric layer, can reduce the absolute value of the difference ΔTCV between the temperature coefficients of acoustic velocity at the resonant point and the anti-resonant point. The sum total of the Al conversion thickness of the electrode layer is the Al conversion thickness of the electrode finger. Moreover, an Al conversion thickness of the electrode finger normalized by the thickness of the piezoelectric layer is a normalized thickness of the electrode finger. When the normalized thickness of the electrode finger is about 1 or larger, similar to the present preferred embodiment, the Al conversion thickness of the electrode finger is at or larger than the thickness of the piezoelectric layer.

Through simulation, in each of cases in which the temperature coefficient of elasticity TCm of the electrode finger was varied, a relationship between the normalized thickness of the electrode finger and the difference ΔTCV in the temperature coefficient of acoustic velocity was derived. More specifically, moduli of elasticity c11 and c44 of the electrode finger are changed. The moduli of elasticity c11 and c44 are the same or substantially the same value. A material property value of the electrode finger, other than the modulus of elasticity, is the same or substantially the same as a material property value of Al. The modulus of elasticity c44 contributes to the difference ΔTCV in the temperature coefficient of acoustic velocity. Therefore, herein, the temperature coefficient of elasticity TCm indicates dependence of the modulus of elasticity c44 on temperature. That is, dc44/dT [ppm/K] as a slope of change in the modulus of elasticity c44 with respect to the change in temperature is the temperature coefficient of elasticity TCm [ppm/K]. Example design parameters of the acoustic wave device in the simulation are as follows.
Support substrate: material . . . Si, plane directions . . . (100)
Piezoelectric layer: material . . . 42YX-LiTaO₃, thickness . . . about 300 nm
IDT electrode: material . . . imaginary Al in simulation, electrode finger pitch . . . about 1 μm

FIG. 4 is a diagram illustrating a relationship between the temperature coefficient of elasticity TCm of the electrode finger, the normalized thickness of the electrode finger, and the difference ΔTCV in the temperature coefficient of acoustic velocity.

In a case of lithium tantalate bulk having a thickness larger than about 3λ, the difference ΔTCV between the temperature coefficients of acoustic velocity at the resonant point and the anti-resonant point of the SH mode is approximately −30 ppm/K. As illustrated in FIG. 4, in the case of the present preferred embodiment in which the normalized thickness of the electrode finger is about 1 or larger, that is, at or larger than the thickness of the piezoelectric layer, in a wide range of the temperature coefficient of elasticity TCm of the electrode finger, the difference ΔTCV in the temperature coefficient of acoustic velocity can be made to about −30 ppm/K or larger. Therefore, it can be seen that, in the wide range of the temperature coefficient of elasticity TCm of the electrode finger, the absolute value of the difference ΔTCV in the temperature coefficient of acoustic velocity can be made small. Moreover, the normalized thickness of the electrode finger is preferably, for example, about 1.1 or larger. Therefore, regardless of the temperature coefficient of elasticity TCm of the electrode finger, the absolute value of the difference ΔTCV in the temperature coefficient of acoustic velocity can be made small.

When the thickness of the piezoelectric layer is relatively large, the piezoelectric layer is predominant to the temperature characteristics. On the other hand, in the present preferred embodiment, the normalized thickness of the electrode finger is, for example, about 1 or larger, and the thickness of the piezoelectric layer is relatively small, whereas the thickness of the electrode finger is relatively large. Therefore, contribution of the electrode finger to the temperature characteristics is increased, and the absolute value of the difference ΔTCV in the temperature coefficient of acoustic velocity can be reduced. As the value of the normalized thickness of the electrode finger increases, mass addition by the electrode finger increases, which makes the contribution of the electrode finger to the temperature characteristics larger. Therefore, as the value of the normalized thickness of the electrode finger increases, the absolute value of the difference ΔTCV in the temperature coefficient of acoustic velocity can be reduced.

Moreover, through simulation, in each of cases in which the temperature coefficient of elasticity TCm of the electrode finger was varied, a relationship between the normalized thickness of the electrode finger and a temperature coefficient of acoustic velocity TCVr at the resonant point was derived.

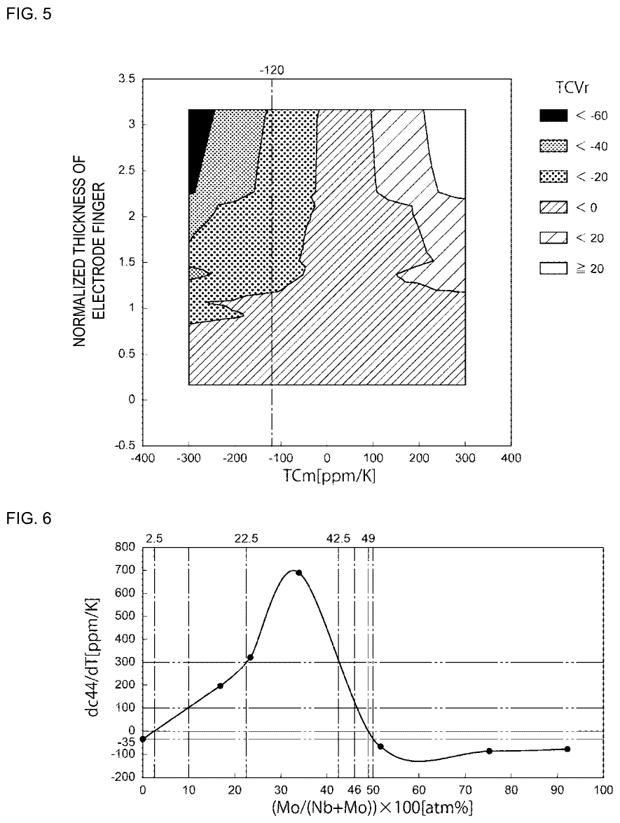

FIG. 5 is a diagram illustrating the relationship between the temperature coefficient of elasticity TCm of the electrode finger, the normalized thickness of the electrode finger, and the temperature coefficient of acoustic velocity TCVr at the resonant point.

In a case of lithium tantalate bulk having a thickness larger than about 3λ, the temperature coefficient of acoustic velocity TCVr at the resonant point of the SH mode is approximately −40 ppm/K. As illustrated in FIG. 5, in the case of the present preferred embodiment in which the normalized thickness of the electrode finger is about 1 or larger, that is, at or larger than the thickness of the piezoelectric layer, when the temperature coefficient of elasticity TCm of the electrode finger is about −120 ppm/K or larger, the temperature coefficient of acoustic velocity TCVr can be made to about −40 ppm/K or larger, for example. As described above, the temperature coefficient of elasticity TCm of the electrode finger is preferably, for example, about −120 ppm/K or larger. Therefore, the temperature characteristics can more certainly be improved.

As described above, when the thickness of the electrode finger is larger than the thickness of the piezoelectric layer, contribution of the electrode finger to the temperature characteristics increases. More specifically, contribution of the thickness and the temperature coefficient of elasticity TCm of the electrode finger to the temperature characteristics increases. Table 1 shows the temperature coefficients of elasticity TCm of representative materials used for the IDT electrode.

TABLE 1

| | TCm |
|---|---|
| Material | [ppm/K] |
| Al | −590 |
| Cu | −270 |
| Mo | −130 |
| W | -99 |

As shown in Table 1, the material whose temperature coefficient of elasticity TCm is comparatively large is, for example, Mo and W. Particularly, the temperature coefficient of elasticity TCm of W is about −120 ppm/K or larger. However, in these materials, electrical resistance is comparatively high. On the other hand, in Al and Cu, although electrical resistance is low, the temperature coefficients of elasticity TCm are small.

In this respect, for example, Nb, Pd, NiFe, and an alloy including at least one of Nb and Pd have comparatively large temperature coefficients of elasticity TCm and comparatively low electrical resistance. The alloy including Nb is, for example, NbMo. In FIG. 6, dc44/dT of NbMo is illustrated. As described above, dc44/dT indicating the dependence of the modulus of elasticity c44 on temperature is the temperature coefficient of elasticity TCm. FIG. 6 is based on description in Hubbell, et al., Physics Letters A 39.4 (1972): 261-262.

FIG. 6 is a diagram illustrating a relationship between a percentage of Mo content and dc44/dT in NbMo. The relationship illustrated in FIG. 6 shows a relationship at the temperature of about 25° C., for example. When the percentage of Mo content is 0%, Nb is shown.

As illustrated in FIG. 6, dc44/dT of Nb is about −35 ppm/K. It can be seen that, in a range where the percentage of Mo content in NbMo is about 33.6 atm % or lower, dc44/dT increases as the percentage of Mo content increases. Furthermore, when the percentage of Mo content is about 33.6 atm %, dc44/dT becomes the maximum value. The percentage of Mo content is preferably, for example, about 50 atm % or lower. In this case, dc44/dT of NbMo can be made larger than dc44/dT of Nb. The percentage of Mo content is more preferably, for example, about 2.5 atm % or higher and about 49 atm % or lower. In this case, dc44/dT can be made to 0 ppm/K or larger. The percentage of Mo content is further preferably, for example, about 10 atm % or higher and about 46 atm % or lower. In this case, dc44/dT can be made to about 100 ppm/K or larger. The percentage of Mo content is more preferably, for example, about 22.5 atm % or higher and about 42.5 atm % or lower. In this case, dc44/dT can be made to about 300 ppm/K or larger.

Therefore, by NbMo as described above being used for the IDT electrode, the temperature coefficient of elasticity TCm of the electrode finger can be increased. Thus, the absolute value of the difference ΔTCV between the temperature coefficients of acoustic velocity at the resonant point and the anti-resonant point can be reduced. Moreover, since electrical resistance of NbMo is comparatively low, electrical resistance of the IDT electrode can also be made low.

Meanwhile, in the present preferred embodiment illustrated in FIG. 2, the piezoelectric layer 6 is provided directly on the high-acoustic-velocity support substrate 4 as the high-acoustic-velocity material layer. However, the layer configuration of the piezoelectric substrate 2 and the high-acoustic-velocity material layer are not limited to those described above.

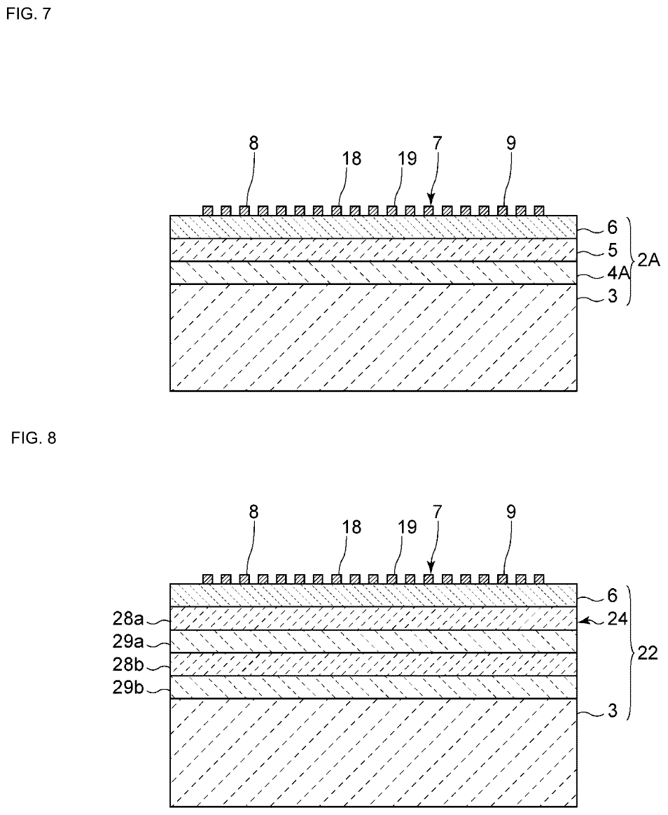

For example, in a modification of the first preferred embodiment of the present invention illustrated in FIG. 7, a piezoelectric substrate 2A includes a support substrate 3, a high acoustic velocity film 4A as the high-acoustic-velocity material layer, a low acoustic velocity film 5, and the piezoelectric layer 6. The high acoustic velocity film 4A is provided on the support substrate 3. The low acoustic velocity film 5 is provided on the high acoustic velocity film 4A. The piezoelectric layer 6 is provided on the low acoustic velocity film 5. In this modification, the piezoelectric layer 6 is provided indirectly on the high acoustic velocity film 4A as the high-acoustic-velocity material layer, with the low acoustic velocity film 5 interposed therebetween. Also in this modification, similarly to the first preferred embodiment, the absolute value of the difference ΔTCV between the temperature coefficients of acoustic velocity at the resonant point and the anti-resonant point can be reduced.

The low acoustic velocity film 5 is a film in which an acoustic velocity is relatively low. More specifically, an acoustic velocity of a bulk wave which propagates in the low acoustic velocity film 5 is lower than an acoustic velocity of a bulk wave which propagates in the piezoelectric layer 6. As a material of the low acoustic velocity film 5, for example, glass, silicon oxide, silicon oxynitride, lithium oxide, tantalum pentoxide, or a material whose main component is a compound in which fluorine, carbon, or boron is added to silicon oxide may be used.

As a material of the support substrate 3, for example, a piezoelectric material (for example, aluminum oxide, lithium tantalate, lithium niobate, and a crystal), various types of ceramics (for example, alumina, sapphire, magnesia, silicon nitride, aluminum nitride, silicon carbide, zirconia, cordierite, mullite, steatite, and forsterite), a dielectric (for example, diamond and glass), a semiconductor (for example, silicon and gallium nitride), resin, or the like may be used.

Furthermore, for example, the piezoelectric substrate may be a multilayer body including the high-acoustic-velocity support substrate, the low acoustic velocity film, and the piezoelectric layer. Alternatively, the piezoelectric substrate may be a multilayer body including the support substrate, the high acoustic velocity film, and the piezoelectric layer. Also in these cases, similarly to the first preferred embodiment, the absolute value of the difference ΔTCV between the temperature coefficients of acoustic velocity at the resonant point and the anti-resonant point can be reduced.

As described above, in preferred embodiments of the present invention, the piezoelectric substrate is not limited to including the high-acoustic-velocity material layer, but may include the acoustic reflection layer. As an example of the case in which the piezoelectric substrate includes the acoustic reflection layer, a second preferred embodiment and a third preferred embodiment of the present are described below. In each of the second preferred embodiment and the third preferred embodiment, a configuration of the piezoelectric substrate is different from the configuration of the first preferred embodiment. Other than the point described above, the acoustic wave devices in the second preferred embodiment and the third preferred embodiment have configurations the same as or similar to the configuration of the acoustic wave device 1 in the first preferred embodiment. Also in the second preferred embodiment and the third preferred embodiment, the absolute value of the difference ΔTCV between the temperature coefficients of acoustic velocity at the resonant point and the anti-resonant point can be reduced.

FIG. 8 is an elevational cross-sectional view of the acoustic wave device according to the second preferred embodiment.

A piezoelectric substrate 22 of the present preferred embodiment includes the support substrate 3, an acoustic reflection film 24, and the piezoelectric layer 6. The acoustic reflection film 24 is provided on the support substrate 3. The piezoelectric layer 6 is provided on the acoustic reflection film 24. The acoustic reflection film 24 corresponds to the acoustic reflection layer.

The acoustic reflection film 24 is a multilayer body including a plurality of acoustic impedance layers. More specifically, the acoustic reflection film 24 includes a plurality of low acoustic impedance layers and a plurality of high acoustic impedance layers. The low acoustic impedance layer is a layer with a relatively low acoustic impedance. The plurality of low acoustic impedance layers of the acoustic reflection film 24 include a low acoustic impedance layer 28a and a low acoustic impedance layer 28b. On the other hand, the high acoustic impedance layer is a layer with a relatively high acoustic impedance. The plurality of high acoustic impedance layers of the acoustic reflection film 24 include a high acoustic impedance layer 29a and a high acoustic impedance layer 29b. The low acoustic impedance layers and the high acoustic impedance layers are laminated alternately. The low acoustic impedance layer 28a is the layer positioned closest to the piezoelectric layer 6 in the acoustic reflection film 24.

The acoustic reflection film 24 includes, for example, two low acoustic impedance layers and two high acoustic impedance layers. However, it is only required that the acoustic reflection film 24 includes at least one low acoustic impedance layer and one high acoustic impedance layer. As a material of the low acoustic impedance layer, for example, silicon oxide, aluminum, or the like may be used. As a material of the high acoustic impedance layer, for example, metal such as platinum and tungsten or a dielectric such as aluminum nitride and silicon nitride may be used.

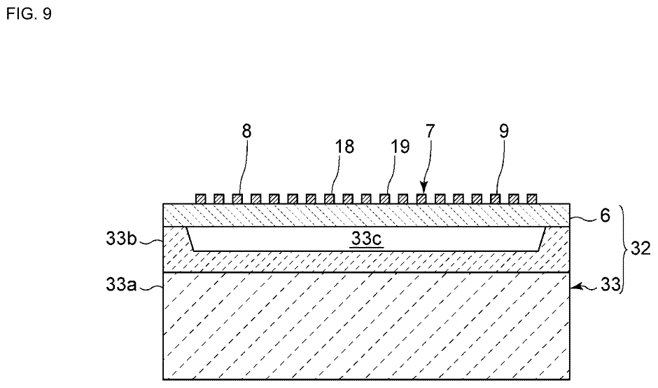

FIG. 9 is an elevational cross-sectional view of the acoustic wave device according to the third preferred embodiment.

A piezoelectric substrate 32 of the present preferred embodiment includes a support 33 and the piezoelectric layer 6. The support 33 includes a support substrate 33a and a dielectric layer 33b. The support substrate 33a has a configuration similar to the configuration of the support substrate 3 in the modification of the first preferred embodiment and the second preferred embodiment. The dielectric layer 33b is provided on the support substrate 33a. The piezoelectric layer 6 is provided on the dielectric layer 33b. The support 33 includes a hollow portion 33c. More specifically, the hollow portion 33c is a concave portion provided to the dielectric layer 33b. By the concave portion being sealed by the piezoelectric layer 6, a hollow portion is provided. When seen in plan view, the hollow portion 33c overlaps with at least a portion of the IDT electrode 7. In the present preferred embodiment, the hollow portion 33c corresponds to the acoustic reflection layer. Herein, “seen in plan view” indicates a direction to see from an upper side in FIG. 2, FIG. 9, or the like.

The hollow portion 33c may be provided only to the support substrate 33a, or may be provided over the support substrate 33a and the dielectric layer 33b. Alternatively, the hollow portion 33c may be a through-hole provided to at least one of the support substrate 33a and the dielectric layer 33b. The support 33 may include only the support substrate 33a. In this case, it is only required that the support substrate 33a is provided with the hollow part 33c.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including an acoustic reflection layer and a piezoelectric layer on the acoustic reflection layer; and
an IDT electrode on the piezoelectric substrate and including a plurality of electrode fingers; wherein
when a wavelength defined by an electrode finger pitch of the IDT electrode is λ, a thickness of the piezoelectric layer is about 3λ or smaller;
the plurality of electrode fingers include at least one electrode layer; and
a sum total of a thickness of the at least one electrode layer converted based on a density ratio of the at least one electrode layer and Al assuming that the at least one electrode layer includes Al is a same or larger than the thickness of the piezoelectric layer.

2. The acoustic wave device according to claim 1, wherein
the acoustic reflection layer is an acoustic reflection film; and
the acoustic reflection film includes at least one low acoustic impedance layer with a relatively low acoustic impedance, and at least one high acoustic impedance layer with a relatively high acoustic impedance, and the low acoustic impedance layer and the high acoustic impedance layer are laminated alternately.

3. The acoustic wave device according to claim 1, wherein
the piezoelectric substrate includes a support, and the piezoelectric layer is provided on the support; and
the support includes a hollow portion, and the hollow portion is the acoustic reflection layer.

4. The acoustic wave device according to claim 1, wherein the at least one electrode layer includes a material in which a temperature coefficient of elasticity of a modulus of elasticity c44 is about −120 ppm/K or larger.

5. The acoustic wave device according to claim 1, wherein the at least one electrode layer includes an alloy including at least one of Nb and Pd.

6. The acoustic wave device according to claim 5, wherein the at least one electrode layer includes NbMo.

7. The acoustic wave device according to claim 6, wherein a percentage of Mo content in the NbMo included in the at least one electrode layer is about 50 atm % or lower.

8. The acoustic wave device according to claim 7, wherein the percentage of Mo content in the NbMo included in the at least one electrode layer is about 2.5 atm % or higher and about 49 atm % or lower.

9. The acoustic wave device according to claim 8, wherein the percentage of Mo content in the NbMo included in the at least one electrode layer is about 10 atm % or higher and about 46 atm % or lower.

10. The acoustic wave device according to claim 9, wherein the percentage of Mo content in the NbMo included in the at least one electrode layer is about 22.5 atm % or higher and about 42.5 atm % or lower.

11. The acoustic wave device according to claim 1, wherein the piezoelectric layer includes lithium tantalate.

12. An acoustic wave device comprising:
a piezoelectric substrate including a high-acoustic-velocity material layer and a piezoelectric layer on the high-acoustic-velocity material layer; and
an IDT electrode on the piezoelectric substrate and including a plurality of electrode fingers; wherein
an acoustic velocity of a bulk wave propagating in the high-acoustic-velocity material layer is higher than an acoustic velocity of an acoustic wave propagating in the piezoelectric layer;
when a wavelength defined by an electrode finger pitch of the IDT electrode is λ, a thickness of the piezoelectric layer is about 3λ or smaller;
the plurality of electrode fingers include at least one electrode layer; and
a sum total of a thickness of the at least one electrode layer converted based on a density ratio of the at least one electrode layer and Al assuming that the at least one electrode layer includes Al is a same or larger than the thickness of the piezoelectric layer.

13. The acoustic wave device according to claim 12, wherein the at least one electrode layer includes a material in which a temperature coefficient of elasticity of a modulus of elasticity c44 is about −120 ppm/K or larger.

14. The acoustic wave device according to claim 12, wherein the at least one electrode layer includes an alloy including at least one of Nb and Pd.

15. The acoustic wave device according to claim 14, wherein the at least one electrode layer includes NbMo.

16. The acoustic wave device according to claim 15, wherein a percentage of Mo content in the NbMo included in the at least one electrode layer is about 50 atm % or lower.

17. The acoustic wave device according to claim 16, wherein the percentage of Mo content in the NbMo included in the at least one electrode layer is about 2.5 atm % or higher and about 49 atm % or lower.

18. The acoustic wave device according to claim 17, wherein the percentage of Mo content in the NbMo included in the at least one electrode layer is about 10 atm % or higher and about 46 atm % or lower.

19. The acoustic wave device according to claim 18, wherein the percentage of Mo content in the NbMo included in the at least one electrode layer is about 22.5 atm % or higher and about 42.5 atm % or lower.

20. The acoustic wave device according to claim 1, wherein the piezoelectric layer includes lithium tantalate.
